(19) United States
(12) Patent Application Publication
(10) Pub. No.: US 2012/0003834 A1
(43) Pub. Date: Jan. 5, 2012

(54) Method Of Polishing Chalcogenide Alloy

(76) Inventors: Ja-Ho Koo, Yongin-si (KR); Zhendong Liu, King of Prussia, PA (US); Kaveri Sawant, Glen Mills, PA (US); Kancharla-Arun Kumar Reddy, Bear, DE (US)

(21) Appl. No.: 12/828,441

(22) Filed: Jul. 1, 2010

(51) Int. Cl. H01L 21/306

(52) U.S. Cl. 438/693; 257/E21.23

(57) ABSTRACT

The invention provides a method for chemical mechanical polishing of a substrate. The invention comprises providing a substrate, wherein the substrate comprises a chalcogenide phase change alloy and providing a chemical mechanical polishing composition, wherein the chemical mechanical polishing composition comprises, by weight percent, water, 0.1 to 30 abrasive, at least one polishing agent selected from 0.05 to 5 halogen compound, 0.05 to 5 phthalic acid, 0.05 to 5 phthalic anhydride and salts, derivatives and mixtures thereof and wherein the chemical mechanical polishing composition has a pH of 2 to less than 7. A chemical mechanical polishing pad polishes the substrate with the chemical mechanical polishing pad and the chemical mechanical polishing composition to selectively or non-selectively remove the chalcogenide phase change alloy from the substrate.

The present invention relates to chemical mechanical polishing compositions and methods of using the same. More particularly, the present invention relates to chemical mechanical polishing compositions for polishing a substrate having a phase change alloy (e.g., germanium-antimony-tellurium phase change alloy).

Phase change random access memory (PRAM) devices that use phase change materials that can be electrically transitioned between an insulating, generally amorphous state and a conductive, generally crystalline state have become a leading candidate for the next generation of memory devices. These next generation PRAM devices may replace conventional solid state memory devices such as dynamic random access memory—DRAM—devices; static random access memory—SRAM—devices, erasable programmable read only memory—EPROM—devices, and electrically erasable programmable read only memory—EEPROM—devices that employ microelectronic circuit elements for each memory bit. These conventional solid state memory devices consume a lot of chip space to store information, thus limiting chip density; and are also relatively slow to program.

Phase change materials useful in PRAM devices include chalcogenide materials such as, germanium-tellurium (Ge—Te) and germanium-antimony-tellurium (Ge—Sb—Te) phase change alloys. The manufacture of PRAM devices include chemical mechanical polishing steps in which chalcogenide phase change materials are selectively removed and the device surface is planarized.

An early example of a selective chalcogenide phase change material slurry is U.S. Pat. No. 7,682,976 to Jong-Young Kim. This slurry varies components to adjust germanium-antimony-tellurium (GST) and TEOS dielectric removal rates. In the Kim formulation, increasing the abrasive concentration increases the TEOS removal rate. In the absence of azole inhibitor, increasing hydrogen peroxide increases the GST removal rate. This slurry adjusts GST selectivity in relation to TEOS removal rate, but lacks disclosure for adjusting GST removal rate in relation to a silicon nitride removal rate.

There exists a need for chemical mechanical polishing (CMP) compositions capable of selectively or non-selectively removing chalcogenide phase change alloy in relation to silicon nitride and dielectrics for the manufacture of PRAM devices. The selective slurries must provide acceptable phase change alloy removal rates with minimal silicon nitride and dielectric removal rates. For non-selective slurries, the composition must provide a balanced combination of phase change alloy removal rates with silicon nitride and dielectric removal rates that satisfy a particular integration scheme.

### STATEMENT OF THE INVENTION

An aspect of the invention includes a method for chemical mechanical polishing of a substrate, comprising: providing a substrate, wherein the substrate comprises a chalcogenide phase change alloy; providing a chemical mechanical polishing composition, wherein the chemical mechanical polishing composition comprises, by weight percent, water, 0.1 to 30 abrasive, at least one polishing agent selected from 0.05 to 5 halogen compound, 0.05 to 5 phthalic acid, 0.05 to 5 phthalic anhydride and salts, derivatives and mixtures thereof and wherein the chemical mechanical polishing composition has a pH of 2 to less than 7; providing a chemical mechanical polishing pad; and polishing the substrate with the chemical mechanical polishing pad and the chemical mechanical polishing composition to selectively or non-selectively remove the chalcogenide phase change alloy from the substrate.

Another aspect of the invention includes A method for chemical mechanical polishing of a substrate, comprising: providing a substrate, wherein the substrate comprises a chalcogenide phase change alloy; providing a chemical mechanical polishing composition, wherein the chemical mechanical polishing composition comprises, by weight percent, water, 0.2 to 20 abrasive, at least one polishing agent selected from 0.1 to 5 halogen compound and 0.1 to 4 phthalic acid, 0.1 to 4 phthalic anhydride and salts, derivatives and mixtures thereof and wherein the chemical mechanical polishing composition has a pH of 2.5 to 6; providing a chemical mechanical polishing pad; and polishing the substrate with the chemical mechanical polishing pad and the chemical mechanical polishing composition to selectively or non-selectively remove the chalcogenide phase change alloy from the substrate.

### DETAILED DESCRIPTION

The chemical mechanical polishing method of the present invention is useful for polishing a substrate containing a chalcogenide phase change alloy. The chemical mechanical polishing compositions used in the method of the present invention provide high chalcogenide phase change alloy removal rates with selectivity or non-selectivity over additional materials on substrates, such as those contained in patterned semiconductor wafers.

Substrates suitable for use in the method of the present invention for chemical mechanical polishing comprise a chalcogenide phase change alloy. Preferably, the chalcogenide phase change alloy is selected from a germanium-tellurium phase change alloy and a germanium-antimony-tellurium phase change alloy. Most preferably, the chalcogenide phase change alloy is a germanium-antimony-tellurium phase change alloy.

Substrates suitable for use in the method of the present invention for chemical mechanical polishing optionally further comprise an additional material selected from phosphor silicate glass (PSG), boro-phosphor silicate glass (BPSG), undoped silicate glass (USG), spin-on-glass (SOG), dielectric produced from tetraethyl orthosilicate (TEOS), plasma-enhanced TEOS (PETEOS), flowable oxide (FOx), high-density plasma chemical vapor deposition (HDP-CVD) oxide, and silicon nitride (e.g., Si₃N₄). Preferably, the substrate further comprises an additional material selected from Si₃N₄ and TEOS.

The polishing slurry obtains rate for the chalcogenide phase change alloy with at least one of a halogen compound, phthalic acid and mixtures thereof. If present, the slurry contains 0.05 to 5 weight percent halogen compound. Unless specifically expressed otherwise, all composition amounts refer to weight percent. If present, the slurry preferably contains 0.1 to 4 weight percent of the halogen compound. If present, the slurry preferably contains 0.2 to 3 weight percent of the halogen compound. The halogen compound is preferably at least one selected from bromates, chlorates, iodates and mixtures thereof. Example compounds include ammonium bromate, potassium bromate, ammonium chlorate, potassium chlorate, ammonium iodate, potassium iodate and salts, derivatives and mixtures thereof. For the chalcogenide phase change alloy, the preferred compound is a potassium salt and the preferred halogen is an iodate. Alternatively, the polishing slurry may contain phthalic acid, phthalic anhydride salts, derivatives and mixtures thereof, such as 0.05 to 5 weight percent phthalic acid or 0.05 to 5 weight percent phthalic anhydride. It is possible for the phthalic acid-containing or phthalic anhydride-containing slurries to be oxidizer free. Preferably, if present, the slurry contains 0.1 to 4 weight percent phthalic acid or 0.1 to 4 weight percent phthalic anhydride. Most preferably, if present, the slurry contains 0.2 to 2 weight percent phthalic acid or 0.2 to 2 weight percent phthalic anhydride. In practice, it is possible to add the phthalic acid through the decomposition of a phthalate compound, such as hydrogen-potassium phthalate. Another specific example of phthalic acid compound and phthalic acid derivative is ammonium hydrogen phthalate. Advantageously, the slurry contains both the halogen compound and phthalic acid or phthalic anhydride.

Abrasives suitable for use with the present invention include, for example, inorganic oxides, inorganic hydroxides, inorganic hydroxide oxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), titanium oxide (TiO₂) or combinations comprising at least one of the foregoing oxides. Modified forms of these inorganic oxides, such as, organic polymer-coated inorganic oxide particles and inorganic coated particles can also be utilized, if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. For non-selective or low selective slurries, preferably, the abrasive is a precipitated or agglomerated colloidal silica abrasive. For selective slurries, preferably the abrasive is alumina or ceria.

In some embodiments of the present invention, the abrasive is colloidal silica having an average particle size of ≦400 nm. In some aspects of these embodiments, the colloidal silica has an average particle size of 2 to 300 nm. In some aspects of these embodiments, the colloidal silica has an average particle size of 5 to 250 nm. In some aspects of these embodiments, the colloidal silica has an average particle size of 5 to 100 nm. In some aspects of these embodiments, the colloidal silica has an average particle size of 100 to 250 nm. In other aspects of the invention containing alumina or ceria, the average particle size is 5 to 500 and preferably 10 to 300 nm.

In some embodiments of the present invention, the chemical mechanical polishing composition used contains 0.1 to 30 weight percent abrasive. Preferably, the composition contains 0.2 to 20 weight percent abrasive. Most preferably, the composition contains 0.5 to 10 weight percent abrasive.

The water contained in the chemical mechanical polishing composition used in the chemical mechanical polishing method of the present invention is preferably at least one of deionized and distilled to limit incidental impurities. Typical formulations include a balance water.

The chemical mechanical polishing composition used in the chemical mechanical polishing method of the present invention optionally further comprises additional additives selected from pH titrants, dispersants, surfactants, buffers and biocides.

The chemical mechanical polishing composition used in the chemical mechanical polishing method of the present invention provides efficacy over a pH of 2 to <7. Preferably, the pH is 2.5 to 6; and most preferably, the pH is 3 to 5. Acids suitable for use adjusting the pH of the chemical mechanical polishing composition include, for example, nitric acid, sulfuric acid and hydrochloric acid. Preferably the pH adjustment agent is hydrochloric acid. Suitable bases for pH adjustment include potassium hydroxide, sodium hydroxide, ammonia, tetramethylammonium hydroxide and bicarbonate.

In some embodiments of the present invention, the chalcogenide phase change alloy is a germanium-antimony-tellurium phase change alloy, the abrasive is alumina or ceria and the substrate further comprises Si₃N₄. In these embodiments, the chemical mechanical polishing composition exhibits a germanium-antimony-tellurium phase change alloy removal rate that exceeds its Si₃N₄ removal rate. For example, in these selective embodiments, the chemical mechanical polishing composition exhibits a germanium-antimony-tellurium phase change alloy to Si₃N₄ removal rate selectivity of ≧10:1. Preferably, the chemical mechanical polishing composition exhibits a germanium-antimony-tellurium phase change alloy to Si₃N₄ removal rate selectivity of ≧15:1. Most preferably, the chemical mechanical polishing composition exhibits a germanium-antimony-tellurium phase change alloy to Si₃N₄ removal rate selectivity of ≧20:1.

In some embodiments of the present invention, the chalcogenide phase change alloy is a germanium-antimony-tellurium phase change alloy, the abrasive is alumina or ceria and the substrate further comprises TEOS. In these embodiments, the chemical mechanical polishing composition exhibits a germanium-antimony-tellurium phase change alloy removal rate that exceeds its TEOS removal rate. For example, in these selective embodiments, the chemical mechanical polishing composition exhibits a germanium-antimony-tellurium phase change alloy to TEOS removal rate selectivity of ≧10:1. Preferably, the chemical mechanical polishing composition exhibits a germanium-antimony-tellurium phase change alloy to TEOS removal rate selectivity of ≧15:1. Most preferably, the chemical mechanical polishing composition exhibits a germanium-antimony-tellurium phase change alloy to TEOS removal rate selectivity of ≧20:1.

In some embodiments of the present invention, the chalcogenide phase change alloy is a germanium-antimony-tellurium phase change alloy, the abrasive is colloidal silica and the substrate further comprises Si₃N₄. In these embodiments, the chemical mechanical polishing composition exhibits a germanium-antimony-tellurium phase change alloy removal rate that exceeds or does not exceed its Si₃N₄ removal rate. For example, in these non-selective embodiments, the chemical mechanical polishing composition exhibits a germanium-antimony-tellurium phase change alloy to Si₃N₄ removal rate selectivity of 0.1:1 to 10:1. Preferably, the chemical mechanical polishing composition exhibits a germanium-antimony-tellurium phase change alloy to Si₃N₄ removal rate selectivity of 0.2:1 to 5:1. Most preferably, the chemical mechanical polishing composition exhibits a germanium-antimony-tellurium phase change alloy to Si₃N₄ removal rate selectivity of 0.3:1 to 3:1.

In some embodiments of the present invention, the chalgogenide phase change alloy is a germanium-antimony-tellurium phase change alloy, the abrasive is colloidal silica and the substrate further comprises TEOS. In these embodiments, the chemical mechanical polishing composition exhibits a germanium-antimony-tellurium phase change alloy removal rate that exceeds or does not exceed its TEOS removal rate. For example, in these non-selective embodiments, the chemical mechanical polishing composition exhibits a germanium-antimony-tellurium phase change alloy to TEOS removal rate selectivity of 0.1:1 to 10:1. Preferably, the chemical mechanical polishing composition exhibits a germanium-antimony-tellurium phase change alloy to TEOS removal rate selectivity of 0.2:1 to 5:1. Most preferably, the chemical mechanical polishing composition exhibits a germanium-antimony-tellurium phase change alloy to TEOS removal rate selectivity of 0.3:1 to 3:1.

In some embodiments of the present invention, the chalgogenide phase change alloy is a germanium-antimony-tellurium phase change alloy, the abrasive is a colloidal silica and the chemical mechanical polishing composition exhibits a germanium-antimony-tellurium phase change alloy removal rate of ≧400 Å/min; preferably ≧500 Å/min; most preferably ≧1,000 Å/min with a platen speed of 93 revolutions per minute, a carrier speed of 87 revolutions per minute, a chemical mechanical polishing composition flow rate of 200 ml/min, and a nominal down force of 2.5 psi (17.2 kPa) on a 200 mm polishing machine (e.g., an Applied Materials Mirra 200 mm polishing machine) where the chemical mechanical polishing pad comprises a polyurethane polishing layer containing polymeric hollow core microparticles and a polyurethane impregnated non-woven subpad.

Some embodiments of the present invention will now be described in detail in the following Examples.

### EXAMPLES

### Chemical Mechanical Polishing Compositions

The chemical mechanical polishing slurry compositions tested are described in Table 1. The chemical mechanical polishing composition A is a comparative formulation, which is not within the scope of the claimed invention.

### Example 1

TABLE 1

| | Hy- | | | Col- | | | |
|---|---|---|---|---|---|---|---|
| | drogen | Potas- | | loidal | | | |
| | Per- | sium | Phthalic | Silica | | Cerium | |
| Slur- | oxide | Iodate | Acid | (wt. | Alumina | Oxide | |
| ry | (wt. %) | (wt. %) | (wt. %) | %)* | (wt. %)** | (wt. %)*** | pH |
| A | 1 | 0 | 0 | 5 | 0 | 0 | 4 |
| 1 | 0 | 0 | 0.33 | 5 | 0 | 0 | 4 |
| 2 | 0 | 1.08 | 0.33 | 5 | 0 | 0 | 4 |
| 3 | 0 | 2 | 0.33 | 5 | 0 | 0 | 4 |
| 4 | 0 | 1.08 | 0 | 5 | 0 | 0 | 4 |
| 5 | 0 | 1.08 | 0.66 | 5 | 0 | 0 | 4 |
| 6 | 0 | 1.08 | 0.33 | | 5 | 0 | 4 |
| 7 | 0 | 1.08 | 0.33 | | 0 | 5 | 4 |

All formulations contained a balance de-ionized water and used HCl or KOH for pH adjustment.
*Colloidal silica was Klebosol ® II 1501-50 manufactured by AZ Electronic Materials having an average particle size of 50 nm.
**Alumina was polycrystalline A9225 alumina manufactured by Saint-Gobain Inc. having an average particle size of 230 nm.
***Cerium oxide used was NanoTek SG-3 manufactured by Nanophase Technologies Corporation having an average particle size of 130 nm.

### Polishing Tests

The chemical mechanical polishing compositions described in Table 1 were tested using an Applied Materials, Inc. Mirra 200 mm polishing machine equipped with an ISRM detector system using an IC1010™ polyurethane polishing pad (commercially available from Rohm and Haas Electronic Materials CMP Inc.) under a 2.5 psi (17.2 kPa) down force, a chemical mechanical polishing composition flow rate of 200 ml/min, a platen speed of 93 rpm and a carrier speed of 87 rpm. Germanium-antimony-tellurium (GST) blanket wafers from SKW Associates Inc. were polished under the noted conditions. The GST removal rate data reported in Table 2 was determined by weight loss measurement, and also by the XRR measurement using a Jordan Valley JVX 5200T metrology tool. Si₃N₄ and TEOS blanket wafers from ATDF were polished under the noted conditions. The Si₃N₄ and TEOS removal rates reported in Table 2 were measured using a KLA-Tencor FX200 thickness measurement system.

The results of the polishing tests are presented in Table 2.

TABLE 2

| | Ge—Sb—Te | Si₃N₄ | TEOS | Patterned |
|---|---|---|---|---|
| | Removal Rate | Removal Rate | Removal Rate | Wafer |
| Slurry | (Å/min) | (Å/min) | (Å/min) | Suitability |
| A | 1510 | 328 | 381 | No |
| 1 | 427 | 577 | 437 | Yes |
| 2 | 1595 | 549 | 612 | Yes |
| 3 | 2005 | 549 | 644 | Yes |
| 4 | 1464 | 556 | 584 | Yes |
| 5 | 1796 | 544 | 655 | Yes |
| 6 | 3600 | 45 | 96 | Yes |
| 7 | 3574 | 74 | 139 | Yes |

Although comparative slurry A provided acceptable removal rates for the chalcogenide phase change alloy, it does not provide suitable polishing for patterned semiconductor wafers. The remaining slurries of the invention provide either selective or non-selective options for the chalcogenide phase change alloy that are suitable for patterned wafers. In particular, slurries 1 to 5 containing colloidal silica provided non-selective slurries ranging in Ge—Sb—Te to Si₃N₄ selectivities from about 0.7:1 to 3.6:1 and Ge—Sb—Te to TEOS selectivities from about 1:1 to 3.1:1. In addition the alumina-containing slurry provided a Ge—Sb—Te to Si₃N₄ selectivity of about 80:1 and a Ge—Sb—Te to TEOS selectivity of about 38:1. Similarly, the ceria-containing slurry provided a Ge—Sb—Te to Si₃N₄ selectivity of about 48:1 and a Ge—Sb—Te to TEOS selectivity of about 26:1.

### Example 2

TABLE 3

| | | | | | Col- | Col- | Col- |
|---|---|---|---|---|---|---|---|
| | Potas- | | | | loidal | loidal | loidal |
| | sium | Phthalic | | Colloidal | Silica | Silica | Silica |
| | Iodate | Acid | Alumina | Silica | (wt. | (wt. | (wt. |
| Slurry | (wt. %) | (wt. %) | (wt. %)¹ | (wt. %)² | %)³ | %)⁴ | %)⁵ |
| 8 | 3.13 | 3.2 | 7 | | | | |
| 9 | 1.08 | 0.33 | | 5 | | | |
| 10 | 1.08 | 0.33 | | | 5 | | |
| 11 | 1.08 | 0.33 | | | | 5 | |
| 12 | 1.08 | 0.33 | | | | | 5 |

All formulations contained a balance de-ionized water and used HCl or KOH for pH adjusted to 4.
¹Alumina was polycrystalline A9225 alumina manufactured by Saint-Gobain Inc. having an average size of 230 nm.
²Colloidal silica was Klebosol ® 1686 manufactured by AZ Electronic Materials having an average size of 172 nm.
³Colloidal silica was FUSO PL-2 manufactured by Fuso Chemical Corporation having a primary average size of 24 and a secondary average size of 48 nm.
⁴Colloidal silica was FUSO PL-3 manufactured by Fuso Chemical Corporation having a primary average size of 35 nm and a secondary average size of 70 nm.
⁵Colloidal silica was FUSO PL-7 manufactured by Fuso Chemical Corporation having a primary average size of 75 nm and a secondary average size of 125 nm.

The polishing results for the slurries of Table 3 are below in Table 4.

TABLE 4

| | Ge—Sb—Te | Si₃N₄ | TEOS |
|---|---|---|---|
| | Removal Rate | Removal Rate | Removal Rate |
| Slurry | (Å/min) | (Å/min) | (Å/min) |
| 8 | 1688 | 0 | 0 |
| 9 | 2291 | 1048 | 644 |
| 10 | 2098 | 762 | 621 |
| 11 | 1219 | 682 | 698 |
| 12 | 1954 | 401 | 242 |

The above data illustrate that the polishing formulation of the invention is effective with multiple large particles. In addition, the formulation provided non-selective results for conventional colloidal silica made from inorganic silicates and three sizes of cocoon-shaped colloidal silica The cocoon-shaped colloidal silica contained two primary particles joined into a single secondary particle synthesized from organic compounds and manufactured by Fuso Chemical Corporation.

From the above formulations, it is possible to provide chalcogenide phase change alloys polishing slurries that operate with a variety of integration schemes. For example, it is possible to provide selective or non-selective formulations that polish chalcogenide phase change alloys in a single step. Alternatively, it is possible to provide chalcogenide phase change alloys that polish in two-steps. For example, some integration schemes could use a first selective slurry to remove chalcogenide phase change alloy and stop on the dielectric, such as TEOS. For these integration schemes, then a balanced or non-selective slurry finishes the polishing by removing the chalcogenide phase change alloy and the dielectric layers.

We claim:

1. A method for chemical mechanical polishing of a substrate, comprising:
providing a substrate, wherein the substrate comprises a chalcogenide phase change alloy;
providing a chemical mechanical polishing composition, wherein the chemical mechanical polishing composition comprises, by weight percent, water, 0.1 to 30 abrasive, at least one polishing agent selected from 0.05 to 5 halogen compound, 0.05 to 5 phthalic acid, 0.05 to 5 phthalic anhydride and salts, derivatives and mixtures thereof and wherein the chemical mechanical polishing composition has a pH of 2 to less than 7;
providing a chemical mechanical polishing pad; and
polishing the substrate with the chemical mechanical polishing pad and the chemical mechanical polishing composition to selectively or non-selectively remove the chalcogenide phase change alloy from the substrate.

2. The method of claim 1, wherein the chalcogenide phase change alloy is a germanium-antimony-tellurium phase change alloy; wherein the abrasive contains alumina or ceria; wherein the substrate further comprises Si₃N₄ and TEOS; and, wherein the chemical mechanical polishing composition exhibits a germanium-antimony-tellurium phase change alloy to Si₃N₄ removal rate selectivity of ≧10:1 and a germanium-antimony-tellurium phase change alloy to TEOS removal rate selectivity of ≧10:1.

3. The method of claim 1, wherein the chalcogenide phase change alloy is a germanium-antimony-tellurium phase change alloy; wherein the abrasive is a colloidal silica; wherein the substrate further comprises Si₃N₄ and TEOS; and wherein the chemical mechanical polishing composition exhibits a germanium-antimony-tellurium phase change alloy to Si₃N₄ removal rate selectivity of 0.1:1 to 10:1 and a germanium-antimony-tellurium phase change alloy to TEOS removal rate selectivity of 0.1:1 to 10:1.

4. The method of claim 3 wherein the chemical mechanical polishing composition contains phthalic acid or phthalic anhydride and the chemical mechanical polishing composition is oxidizer-free.

5. The method of claim 1, wherein the chalcogenide phase change alloy is a germanium-antimony-tellurium phase change alloy; wherein the abrasive is a colloidal silica; and wherein the chemical mechanical polishing composition exhibits a germanium-antimony-tellurium phase change alloy removal rate of ≧400 Å/min with a platen speed of 93 revolutions per minute, a carrier speed of 87 revolutions per minute, a chemical mechanical polishing composition flow rate of 200 ml/min, and a nominal down force of 2.5 psi (17.2 kPa) on a 200 mm polishing machine where the chemical mechanical polishing pad comprises a polyurethane polishing layer containing polymeric hollow core microparticles and a polyurethane impregnated non-woven subpad.

6. A method for chemical mechanical polishing of a substrate, comprising:
providing a substrate, wherein the substrate comprises a chalcogenide phase change alloy;
providing a chemical mechanical polishing composition, wherein the chemical mechanical polishing composition comprises, by weight percent, water, 0.1 to 20 abrasive, at least one polishing agent selected from 0.4 to 4 halogen compound 0.1 to 4 phthalic acid 0.1 to 4 phthalic anhydride and salts, derivatives and mixtures thereof and wherein the chemical mechanical polishing composition has a pH of 2.5 to 6;
providing a chemical mechanical polishing pad; and
polishing the substrate with the chemical mechanical polishing pad and the chemical mechanical polishing composition to selectively or non-selectively remove the chalcogenide phase change alloy from the substrate.

7. The method of claim 6, wherein the chalcogenide phase change alloy is a germanium-antimony-tellurium phase change alloy; wherein the abrasive contains alumina or ceria; wherein the substrate further comprises Si₃N₄ and TEOS; and, wherein the chemical mechanical polishing composition exhibits a germanium-antimony-tellurium phase change alloy to Si₃N₄ removal rate selectivity of ≧15:1 and a germanium-antimony-tellurium phase change alloy to TEOS removal rate selectivity of ≧15:1.

8. The method of claim 6, wherein the chalcogenide phase change alloy is a germanium-antimony-tellurium phase change alloy; wherein the abrasive is a colloidal silica; wherein the substrate further comprises Si₃N₄ and TEOS; and wherein the chemical mechanical polishing composition exhibits a germanium-antimony-tellurium phase change alloy to Si₃N₄ removal rate selectivity of 0.2:1 to 5:1 and a germanium-antimony-tellurium phase change alloy to TEOS removal rate selectivity of 0.2:1 to 5:1.

9. The method of claim 8 wherein the chemical mechanical polishing composition contains phthalic acid or phthalic anhydride and the chemical mechanical polishing composition is oxidizer-free.

10. The method of claim 6, wherein the chalcogenide phase change alloy is a germanium-antimony-tellurium phase change alloy; wherein the abrasive is a colloidal silica; and wherein the chemical mechanical polishing composition exhibits a germanium-antimony-tellurium phase change alloy removal rate of ≧500 Å/min with a platen speed of 93 revolutions per minute, a carrier speed of 87 revolutions per minute, a chemical mechanical polishing composition flow rate of 200 ml/min, and a nominal down force of 2.5 psi (17.2 kPa) on a 200 mm polishing machine where the chemical mechanical polishing pad comprises a polyurethane polishing layer containing polymeric hollow core microparticles and a polyurethane impregnated non-woven subpad.
